(19) United States
(12) Patent Application Publication
(10) Pub. No.: US 2025/0021875 A1
(43) Pub. Date: Jan. 16, 2025

(54) BUS TRAINING FOR INTERCONNECTED MEMORY DICE

(71) Applicant: Micron Technology, Inc., Boise, ID (US)

(72) Inventors: Wonjun Choi, Boise, ID (US); Hyunyoo Lee, Boise, ID (US); Smruti Subhash Jhaveri, Boise, ID (US)

(21) Appl. No.: 18/755,355

(22) Filed: Jun. 26, 2024

Related U.S. Application Data
(60) Provisional application No. 63/526,375, filed on Jul. 12, 2023.

(51) Int. Cl. G06N 20/00

(52) U.S. Cl. CPC G06N 20/00

(57) ABSTRACT

Test data associated with a command bus training (CBT) can be separately received at interconnected memory dice. Feedback data that are outputted from the multiple interconnected memory dice in response to the test data can be randomly combined such that combined feedback data is returned as if the feedback data were sent from a single memory die. This provides a flexible and scalable architecture that can accommodate a range of memory densities (e.g., a number of memory dice that are interconnected).

### PRIORITY INFORMATION

This application claims the benefit of U.S. Provisional Application No. 63/526,375, filed on Jul. 12, 2023, the contents of which are incorporated herein by reference.

### TECHNICAL FIELD

The present disclosure relates generally to semiconductor memory and methods, and more particularly, to apparatuses, systems, and methods associated with bus training for interconnected memory dice.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 is a block diagram of a computing system in accordance with a number of embodiments of the present disclosure.

FIG. 2 illustrates a block diagram of a link architecture between interconnected memory dice in accordance with a number of embodiments of the present disclosure.

FIGS. 3A-3B illustrate a portion of one memory die of interconnected memory dice including a pseudo random combine pointer in accordance with a number of embodiments of the present disclosure.

FIG. 4 illustrates a timing diagram for performing a bus training operation on interconnected memory dice in accordance with a number of embodiments of the present disclosure.

FIGS. 5A-5C illustrate a sequence of example output bits generated from a pseudo random combine pointer in accordance with a number of embodiments of the present disclosure.

### DETAILED DESCRIPTION

Systems, apparatuses, and methods related to bus training for interconnected memory dice are described. Establishing a timing parameter for correctly receiving signaling over a bus is referred to as “bus training” (BT). A bus training to train a command bus, such as a command/address (CA) bus, is referred to as “command bus training” (CBT). A CBT can be initiated by sending (from a controller) one or more signals indicative of multiple bits (alternatively referred to as “test data”) on a CA bus. In response to the test data, a memory die sends feedback data as detected on a CA bus back to the controller. The feedback data is sent on a data bus, such as a DQ bus, according to a particular timing parameter. The controller determines whether the two (e.g., test data sent on a CA bus and feedback data received via a DQ bus) matches. If there is a match, the controller instructs memory dice to lock in the timing parameter for receiving data on the command bus. However, if there is no match (bits of the two data differ by any quantity of bits), the controller repeats a CBT process until there is a match between the two and until a suitable timing parameter is ascertained.

In some approaches, multiple interconnected memory dice can be trained individually with respect to the bus (e.g., command bus) by excluding one or more other dice from the training process. As used herein, the term “interconnected memory dice” refers to memory dice that are interconnected together to have at least one shared signal bus to which multiple memory dice are commonly coupled to receive a signal. Individual training of each memory die of the interconnected memory dice can be achieved by masking the other die (or dice) to prevent it from receiving incoming training communications or cause it to decline to respond to the training communication. The masking instruction can be implemented using a multi-purpose command (MPC) or other suitable means.

The memory controller can send an MPC to memory dice to instruct at least one die to be masked. However, some memory systems or standards may not support MPCs, or they may not be available in certain operational modes or scenarios. For example, during initialization, a physical (PHY) layer or PHY chip may not support the issuance of MPCs. Further, training multiple memory dice in a sequential manner may incur increased latencies as compared to training memory dice jointly and/or substantially simultaneously.

Aspects of the present disclosure address the above and other challenges for memory systems including interconnected memory dice. For example, embodiments of the present disclosure are directed to performance of a bus training, such as a CBT, in which interconnected memory dice are jointly and substantially simultaneously trained without relying on an MPC. In embodiments of the present disclosure, memory dice are “interconnected” such that interconnected memory dice are internally connected to one another while some memory dice can be externally connected to the substrate. The memory dice that are connected externally (referred to as “interface memory die”) can act as interface dice for other memory dice (often referred to as “linked memory dice”) that are connected internally thereto. As used herein, an interface die that is externally connected to a substrate can be referred to as “primary memory die” and a linked memory die can be referred to as “secondary memory die”. In some embodiments, the external connections are used for transmitting signals indicative of data to and/or from the interconnected memory dice while the memory dice are internally connected by a cascading connection (e.g., formed via a wire bonding) for transmission of other signals such as command, address, power, ground, etc.

Memory dice that are interconnected together can be trained substantially simultaneously by receiving test data via a shared bus (e.g., a shared CA bus). Feedback data generated at each memory die can be combined prior to being sent on a DQ bus such that combined feedback data can be sent from an interface memory die as if the feedback data were sent from a single memory die. For example, if test data received at each memory die of two interconnected memory dice includes 7 bits, the combined feedback data can also include 7 bits (without being 14 bits=7 bits/memory die*two memory dice). This eliminates a need to mask other memory dice and/or sequentially access interconnected memory dice for respective feedback data.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

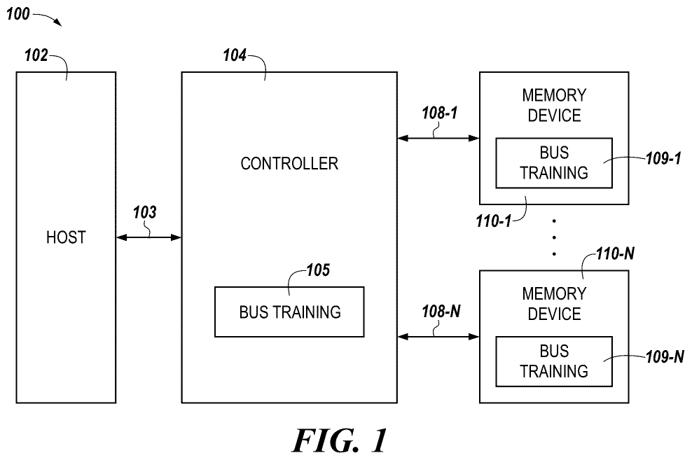

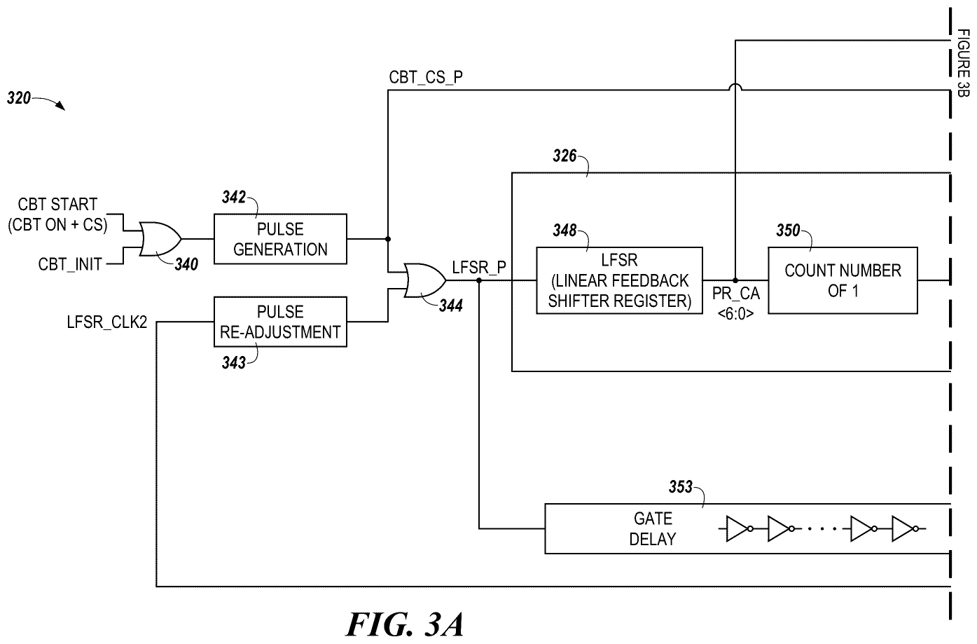

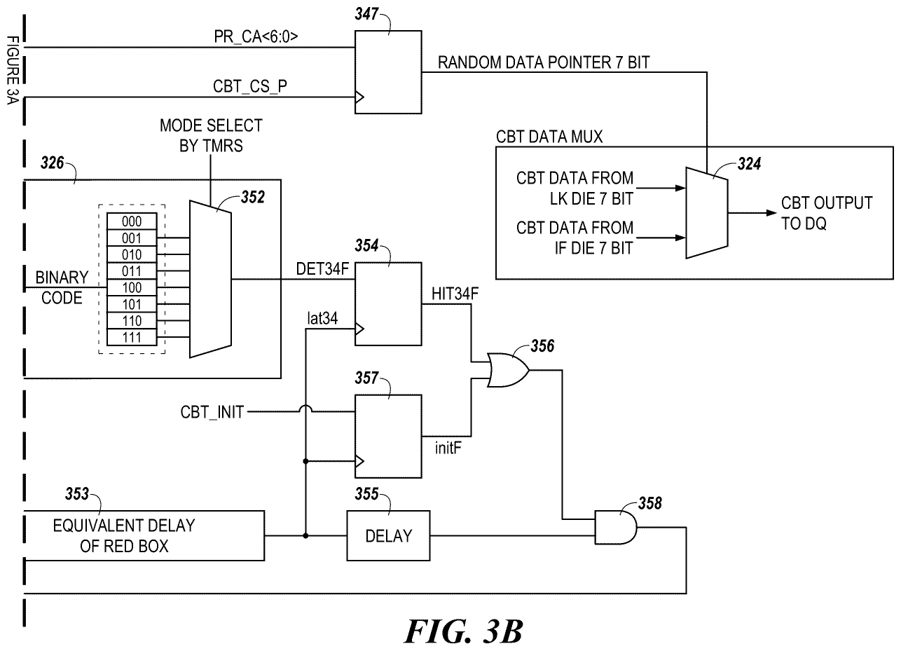

The figures herein follow a numbering convention in which the first digit or digits correspond to the drawing figure number and the remaining digits identify an element or component in the drawing. Similar elements or components between different figures may be identified by the use of similar digits. For example, 109 may reference element “09” in FIG. 1, and a similar element may be referenced as 309 in FIG. 3A or 3B.

Analogous elements within a Figure may be referenced with a hyphen and extra numeral or letter. See, for example, elements 110-1, . . . , 110-N in FIG. 1. Such analogous elements may be generally referenced without the hyphen and extra numeral or letter. For example, elements 110-1, . . . , 110-N may be collectively referenced as 110. As used herein, the designators “N”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of a computing system 100 in accordance with a number of embodiments of the present disclosure. The computing system 100 includes a host 102, a controller 104, and memory devices 110-1, . . . , 110-N, which might also be separately considered an “apparatus.”

The host 102 can include host memory and a central processing unit (not illustrated). The host 102 can be a host system such as a personal laptop computer, a desktop computer, a digital camera, a smart phone, a memory card reader, and/or internet-of-thing enabled device, among various other types of hosts, and can include a memory access device (e.g., a processor and/or processing device). One of ordinary skill in the art will appreciate that “a processor” can intend one or more processors, such as a parallel processing system, a number of coprocessors, etc.

The host 102 can include a system motherboard and/or backplane and can include a number of processing resources (e.g., one or more processors, microprocessors, or some other type of controlling circuitry). The system 100 can include separate integrated circuits or the host 102, the memory controller 104, and the memory devices 110 can be on the same integrated circuit. The system 100 can be, for instance, a server system and/or a high-performance computing (HPC) system and/or a portion thereof.

As illustrated in FIG. 1, a host 102 can be coupled to the controller 104 via an interface 103. The interface 103 can be any type of communication path, bus, or the like that allows for information to be transferred between the host 102 and the controller 104. Non-limiting examples of interfaces can include a peripheral component interconnect (PCI) interface, a peripheral component interconnect express (PCIe) interface, a serial advanced technology attachment (SATA) interface, and/or a miniature serial advanced technology attachment (mSATA) interface, among others. However, in at least one embodiment, the interface 103 is a PCIe 5.0 interface that is compliant with the compute express link (CXL) protocol standard. Accordingly, in some embodiments, the interface 103 can include a flexible bus interconnect and use CXL protocol layers including CXL.io and CXL.mem and can support transfer speeds of at least 32 gigatransfers per second.

The controller 104 can control performance of a memory operation for an access command received from the host 102. The memory operation can be a memory operation to read data (in response to a read request from the host) from or an operation to write data (in response to a write request from the host) to one or more memory devices 110.

In some embodiments, the controller 104 can be a compute express link (CXL) compliant controller. The host interface (e.g., the front end portion of the controller 104) can be managed with CXL protocols and be coupled to the host 102 via an interface configured for a peripheral component interconnect express (PCIe) protocol. CXL is a high-speed central processing unit (CPU)-to-device and CPU-to-memory interconnect designed to accelerate next-generation data center performance. CXL technology maintains memory coherency between the CPU memory space and memory on attached devices, which allows resource sharing for higher performance, reduced software stack complexity, and lower overall system cost. CXL is designed to be an industry open standard interface for high-speed communications, as accelerators are increasingly used to complement CPUs in support of emerging applications such as artificial intelligence and machine learning. CXL technology is built on the PCIe infrastructure, leveraging PCIe physical and electrical interfaces to provide advanced protocol in areas such as input/output (I/O) protocol, memory protocol (e.g., initially allowing a host to share memory with an accelerator), and coherency interface.

The controller 104 can be coupled to the memory devices 110 via channels 108-1, . . . , 108-N, which can be referred to collectively as channels 108. The channels 108 can include various types data buses, such as a sixteen-pin data bus and a two-pin data mask inversion (DMI) bus, among other possible buses. In some embodiments, the channels 108 can be part of a physical (PHY) layer. As used herein, the term “PHY layer” generally refers to the physical layer in the Open Systems Interconnection (OSI) model of a computing system. The PHY layer may be the first (e.g., lowest) layer of the OSI model and can be used transfer data over a physical data transmission medium.

The memory device(s) 110 can provide main memory for the computing system 100 or could be used as additional memory or storage throughout the computing system 100. The memory devices 110 can be various/different types of memory devices. For instance, the memory device can include RAM, ROM, DRAM, SDRAM, PCRAM, RRAM, and flash memory, among others. In embodiments in which the memory device 110 includes persistent or non-volatile memory, the memory device 110 can be flash memory devices such as NAND or NOR flash memory devices. Embodiments are not so limited, however, and the memory device 110 can include other non-volatile memory devices such as non-volatile random-access memory devices (e.g., non-volatile RAM (NVRAM), ReRAM, ferroelectric RAM (FeRAM), MRAM, PCRAM), “emerging” memory devices such as a ferroelectric RAM device that includes ferroelectric capacitors that can exhibit hysteresis characteristics, a memory device with resistive, phase-change, or similar memory cells, etc., or combinations thereof.

As an example, a FeRAM device can include ferroelectric capacitors and can perform bit storage based on an amount of voltage or charge applied thereto. In such examples, relatively small and relatively large voltages allow the ferroelectric RAM device to exhibit characteristics similar to normal dielectric materials (e.g., dielectric materials that have a relatively high dielectric constant) but at various voltages between such relatively small and large voltages the ferroelectric RAM device can exhibit a polarization reversal that yields non-linear dielectric behavior.

As another example, an array of non-volatile memory cells, such as resistive, phase-change, or similar memory cells, can perform bit storage based on a change of bulk resistance, in conjunction with a stackable cross-gridded data access array. Additionally, in contrast to many flash-based memories, the non-volatile memory can perform a write in-place operation, where a non-volatile memory cell can be programmed without the non-volatile memory cell being previously erased.

One example of memory devices 110 is dynamic random access memory (DRAM) operated according to a protocol such as low-power double data rate (LPDDRx), which may be referred to herein as LPDDRx DRAM devices, LPDDRx memory, etc. The “x” in LPDDRx refers to any of a number of generations of the protocol (e.g., LPDDR5). In at least one embodiment, at least one of the memory devices 110-1 is operated as an LPDDRx DRAM device with low-power features enabled and at least one of the memory devices 110-N is operated an LPDDRx DRAM device with at least one low-power feature disabled. In some embodiments, although the memory devices 110 are LPDDRx memory devices, the memory devices 110 do not include circuitry configured to provide low-power functionality for the memory devices 110 such as a dynamic voltage frequency scaling core (DVFSC), a sub-threshold current reduce circuit (SCRC), or other low-power functionality providing circuitry. Providing the LPDDRx memory devices 110 without such circuitry can advantageously reduce the cost, size, and/or complexity of the LPDDRx memory devices 110. By way of example, an LPDDRx memory device 110 with reduced low-power functionality providing circuitry can be used for applications other than mobile applications (e.g., if the memory is not intended to be used in a mobile application, some or all low-power functionality may be sacrificed for a reduction in the cost of producing the memory).

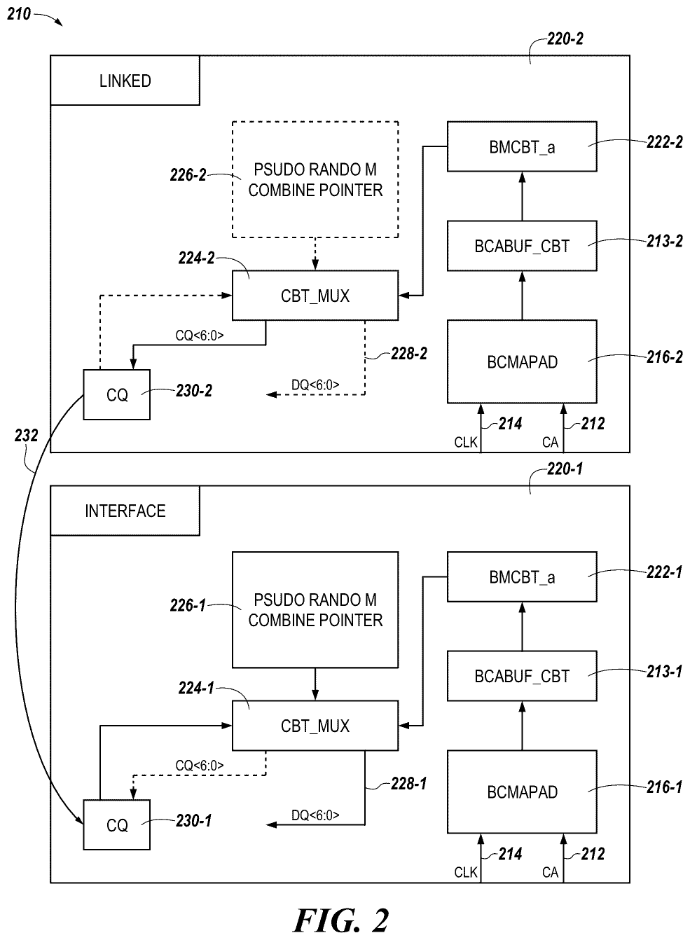

The memory devices 110 can each comprise a number of memory dice (e.g., memory dice 220-1 and 220-2 illustrated in FIG. 2). These memory dice can be interconnected memory dice. As further illustrated in connection with FIG. 2, while memory dice are internally connected, one or more memory dice (e.g., the memory die 220-1 illustrated in FIG. 2) can be connected externally to the substrate to act as interface dice for other memory dice that are connected internally thereto. In some embodiments, these interconnected memory dice can be “stacked” memory dice.

The controller 104 can further include a bus training component 105. Although not shown in FIG. 1 so as to not obfuscate the drawings, the bus training component 105 can include various circuitry to facilitate performance of operations described herein. For example, the bus training component 105 can cause each memory device 110 to perform those operations associated with a bus training. As used herein, the term “bus training” (alternatively referred to as “bus training operation”, “bus training procedure”, etc.) refers to a procedure of establishing a timing parameter for correctly receiving signaling over a bus. Further, a bus training operation performed on a command bus (e.g., a CA bus 212 illustrated in FIG. 2) can be referred to as a command bus training (CBT).

The bus training component 105 can initiate a bus training by issuing commands (e.g., mode register set and/or write commands) to the memory devices 110 and subsequently sending (e.g., transmitting) test data over a bus (e.g., a CA bus 212), to one or more memory devices 110.

The test data can be received at memory dice (e.g., corresponding to one or more ranks) of the memory device 110 according to a first timing parameter. Upon receipt, each memory die can return (e.g., send) the received test data (alternatively referred to as “feedback data”) back to the controller 104. If the feedback data matches the test data as sent from controller 104, the controller 104 can instruct the memory device 110 to lock in the first timing parameter for receiving on the command bus. On the other hand, if the two (e.g., test data and feedback data) do not match, controller 104 can repeat the testing and feedback process with the memory device using a different, second timing parameter and one or more test data. The bus training operation can continue until a suitable timing parameter is ascertained.

The memory devices 110 can include a bus training circuit 109-1, . . . 109-N, which can coordinate bus training procedure to be performed/performed on interconnected memory dice (e.g., memory dice 220-1 and 220-2 illustrated in FIG. 2) of each memory device 110. For example, while the test data may be separately received at each memory die of interconnected memory dice, the feedback data can be output (e.g., sent) from one of interconnected memory dice in a combined manner. For example, if each memory die of interconnected memory dice (e.g., including two memory dice) receives the same test data of 7 bits, feedback data of 7 bits generated at each of two interconnected memory dice can be combined such that feedback data sent back to the controller 104 includes merely 7 bits as opposed to 14 bits. As used herein, the term “output” can be interchangeably used with other terms such as “transfer”, “transmit”, and “send”. The bus training circuit 109 can combine feedback data from interconnected memory dice in a random manner. Further details of randomly combining feedback data from interconnected memory dice are illustrated in FIGS. 2-5. Further, further details of structural components of a bus training circuit is illustrated in FIG. 3.

FIG. 2 illustrates a block diagram of a link architecture between interconnected memory dice 220-1 and 220-2 (collectively referred to as memory dice 220) in accordance with a number of embodiments of the present disclosure. More particularly, FIG. 2 illustrates a bus training circuit 109 within each memory die 220-1, 220-2 in a further detailed manner.

FIG. 2 illustrates two memory dice 220-1 and 220-2; however, embodiments are not limited to a particular quantity of memory dice that can be interconnected (e.g., coupled) together in a similar manner illustrated in FIG. 2. Each memory die 220 is not illustrated in its entirety in FIG. 2 and can further include other portions that are not illustrated in FIG. 2. For example, each memory die 220 can include an array of memory cells where data externally received can be written to or data can be read from. Although embodiments are not so limited, the memory dice 220-1 and 220-2 can correspond to a rank. As illustrated in FIG. 2, memory dice 220-1 and 220-2 that are interconnected together can be “stacked” also (e.g., stacked in a vertical manner).

A memory die 220-1 can be a primary memory die that is externally connected to a substrate, while a memory die 220-2 can be a secondary memory die that is not coupled to the substrate, but is internally coupled to the primary memory die (e.g., memory die 220-1) to communicate data via the primary memory die. As shown in FIG. 2, a secondary memory die 220-2 is internally coupled to a primary memory die 220-1 via a CQ bus 232 (alternatively referred to as “wire link”), which can be formed via a wire bonding.

As shown in FIG. 2, memory dice 220-1, 220-2 respectively include CA pads 216-1, 216-2, which can receive clock and/or CA signals, such as a clock signal (“CLK” as shown in FIG. 2) sent via a CLK bus 214 and a CA signal (“CA” as shown in FIG. 2) sent via a CA bus 212. In a number of embodiments, memory dice of interconnected memory dice, such as memory dice 220-1, 220-2 can be coupled to a same CA bus 212 to substantially simultaneously receive CA signals. As used herein, the term “substantially” means that the characteristic need not be absolute, but is close enough so as to achieve the advantages of the characteristic. For example, “substantially simultaneously” is not limited to operations that are performed absolutely simultaneously and can include timings that are intended to be simultaneously but due to manufacturing limitations may not be precisely simultaneously. A clock signal that can be received via a CLK bus 214 can represent a system clock such as a CA clock and various components of the respective memory die 220 can operate based on the clock signal.

During a CBT operation (which can be initiated by setting one or more particular mode register bits, such as MR16 OP [5:4]), one or more CA signals received at memory dice 220-1 and 220-2 can be indicative of a sequence of commands (e.g., mode register set (MRS) commands, mode register write (MRW) commands, etc.), test data of one or more CBT operations, etc. The CA signals received at memory dice 220-1 and 220-2 can be buffered at respective buffers 218-1 and 218-2. Each selector 222-1 and 222-2 (“BMCBT_a” as shown in FIG. 2) can selectively send bits (e.g., one set of test data) buffered at the respective buffer 218 to a selector 224-1, 224-2 (“CBT MUX” as shown in FIG. 2). For example, the selector 222 can select one set of test data received at the buffer 218 prior to another set of test data and send the selected test data to the selector 224.

As illustrated in FIG. 2, each selector 224 can receive inputs from a respective selector 222 and a respective CQ pad 230 as well as a control signal from a pseudo random combine pointer 226. In a particular example, such as a CBT operation, a selector 224-2 of a linked memory die 220-2 provides feedback data (corresponding to test data received at the memory die 220-2) to a CQ pad 230-2 to further send the feedback data to (e.g., to a CQ pad 230-1 of) an interface memory die 220-1 via a CQ bus 232. The feedback data received at the memory die 220-1 can be input to a selector 224-1 of the memory die 220-1. Continuing with the CBT operation example, the selector 224-1 also receives feedback data (corresponding to test data received at the memory die 220-1) as an input.

The selector 224-1 can combine both inputs (e.g., first feedback data from a memory die 220-1 and second feedback data from a memory die 220-2) to generate combined feedback data. For example, if each one of first and second feedback data include 7 bits (e.g., 7 bits of feedback data from memory die 220-1 and 7 bits of feedback data from memory die 220-2), the combined feedback data can also include 7 bits with 3 bits from one (e.g., first or second) feedback data and 4 bits from another (e.g., first or second) feedback data, although embodiments are not limited to a particular quantity of bits of first or second feedback data that can be included in the combined feedback data.

As illustrated in FIG. 2, memory dice 220-1 and 220-2 respectively include pseudo random combine pointers 226-1 and 226-2. Each pseudo random pointer 226 can instruct a respective selector 224 on how to combine inputs received at the respective selector 224 to generate a combined output.

At least while a bus training operation, such as a CBT operation, is being performed, a pseudo random combine pointer 226-2 of a linked memory die can be disabled, while a pseudo random combine pointer 226-1 of the interface memory die is enabled and used for the bus training operation. During the bus training operation, a pseudo random combine pointer 226-1 can provide “random pointer” bits whose quantity is equal to a quantity of each input received at the selector 224-1.

The selector 224-1 can combine input bits (e.g., test data received from both memory dice 220-1 and 220-2) as indicated by the “random pointer” bits. For example, assuming that a binary value of “0” represents a memory die 220-1 and a binary value of “1” represents a memory die 220-2 and “random pointer” bits received at the selector 224-1 are “0100111”, the selector 224-1 generates the combined output bits by including the feedback data from the memory die 220-1 on those bit positions (e.g., first, third, and fourth bits) corresponding to “random pointer” bits having “0” and the feedback data from the memory die 220-2 on those bit positions (e.g., second, fifth, sixth, and seventh bits) corresponding to “random pointer” bits having “1”.

Test data can be sent (e.g., transmitted) from the memory die 220-1 via an external data bus 228 (e.g., data input/output bus, which is also referred to in the art as a “DQ”) and further back to the controller (e.g., the controller 104 illustrated in FIG. 1). As described herein, a memory die 220-2 as a linked die may not be coupled to the external data bus 228. Although embodiments are not so limited, the external data bus 236 can be 7-bit wide data bus, marked “DQ<6:0>” in FIG. 2.

In some embodiments, the controller 104 can enforce a pseudo random combine pointer 226 to operate independently of (e.g., regardless of) a bus training operation (which can be initiated by setting a particular mode register bit, such as MR16 OP[4]), for example, to test and/or determine tendency, in which the pseudo random combine pointer 226 operates.

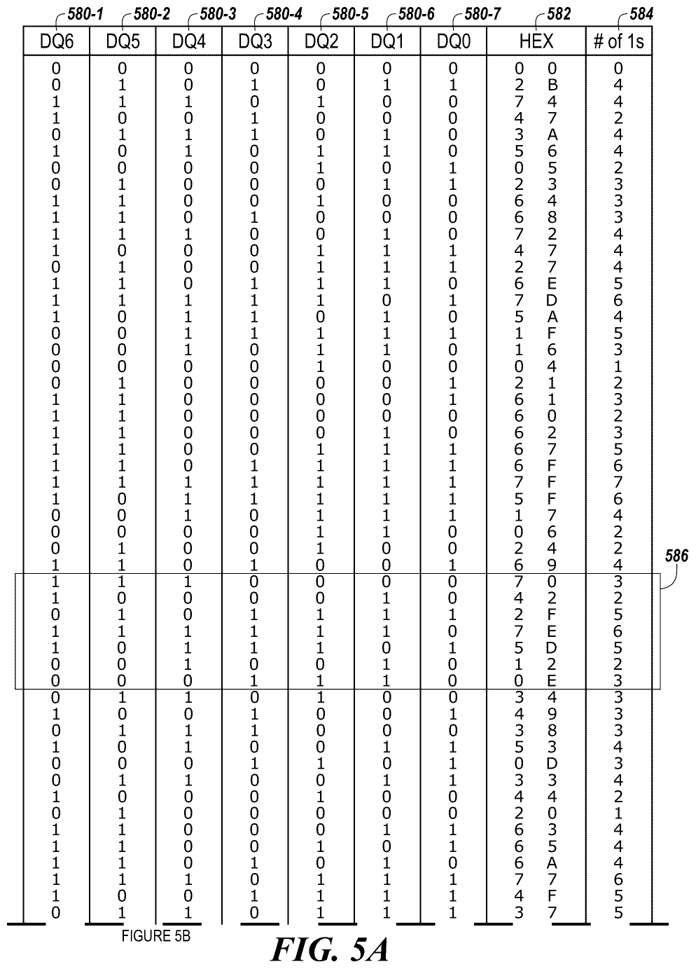

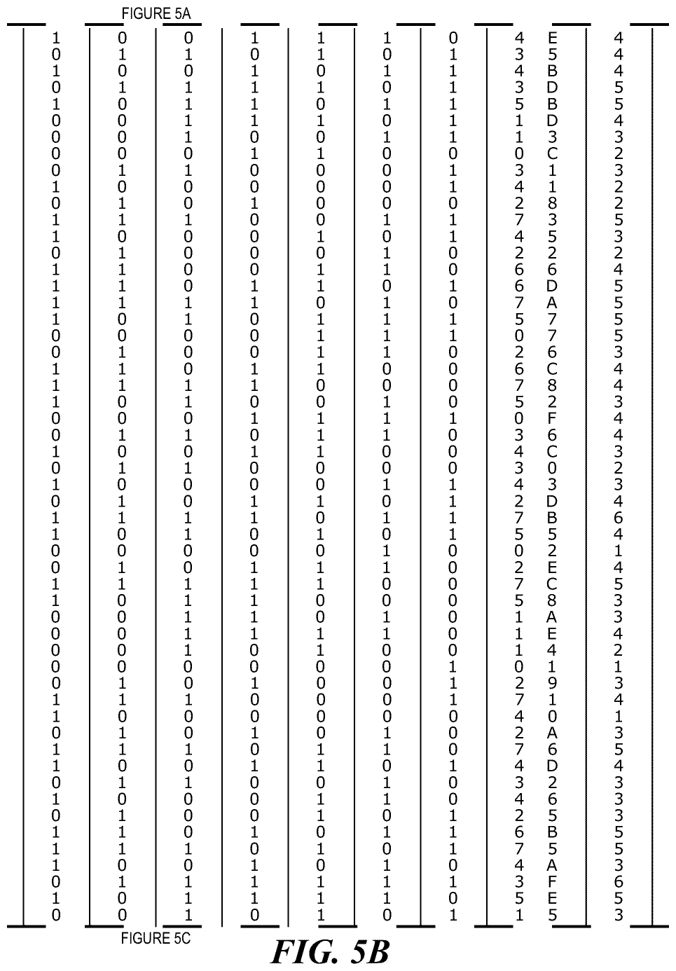

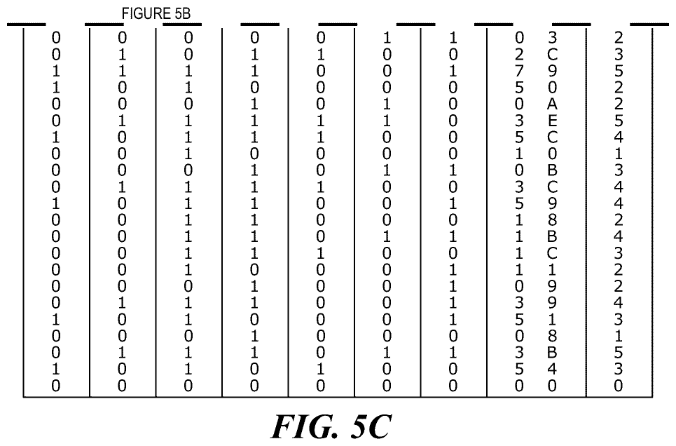

For example, the controller 104 can enforce one memory die (e.g., memory die 220-1) to send “LOW” signals (e.g., corresponding to a binary value of “0”) and enforce another memory die (e.g., memory die 220-1) to send “HIGH” signals (e.g., corresponding to a binary value of “1”) respectively from selectors 222-1 and 222-2 to the selectors 224-1 and 224-2. The “LOW” signal are further sent to the memory die 220-1. Continuing with this example, the selector 224-1 receives input bits (e.g., 7 bits) from the memory die 220-2 with each bit being “1” and input bits (e.g., 7 bits) from the memory die 220-1 with each bit being “0”. The inputs received at the selector 224-1 can be combined to be included in output bits as instructed by the pseudo random combine pointer 226 and as described herein. Since whether bits of output bits are from memory die 220-1 or 220-2 are ascertainable based on respective binary values of the bits, the output bits can indeed indicate random pointer bits generated at the pseudo random combine pointer 226. For example, output bits of “0100111” received (e.g., at the controller 104) from the memory die 220-1 further indicates that input bits from memory dice 220-1 and 220-2 are combined using random pointer bits of “0100111”. Although embodiments are not so limited, the controller 104 can enforce memory dice 220 to continuously send multiple sets of output bits in the above-described manner. Further details of this testing of pseudo random combine pointer 226 are described in connection with FIGS. 5A-5C.

FIGS. 3A-3B illustrate a block diagram illustrating a portion of one memory die (e.g., bus training circuit 309) of interconnected memory dice including a pseudo random combine pointer 326 in accordance with a number of embodiments of the present disclosure. The bus training circuit 309 illustrated in FIG. 3A-3B can be analogous to a bus training circuit 109 of a respective memory die 309, such as interface die 220-1 illustrated in FIG. 2.

As shown in FIG. 3A, the bus training circuit 309 includes a logic gate 340 (e.g., XOR gate) that can receive inputs, such as a signal indicative of a bus training command (“CBT start” shown in FIG. 3A) to initiate and perform a bus training operation and a signal indicative of a bus training initialization command (“CBT_INIT” shown in FIG. 3A) to initiate and perform a bus training initialization operation. Although embodiments are not so limited, a bus training operation performed on interconnected memory dice (including a bus training circuit 309) can be a CBT operation. The logic gate 340 can generate and send an output signal to a pulse generation component 342 in response to receiving the command.

The pulse generation component 342 can generate and send a signal (“CBT_CS_P” shown in FIG. 3A and in forms of pulses) to a logic gate 344 (e.g., XOR gate) as well as to a sequential logic circuit 347 (e.g., flip-flop) in response to receiving the signal from the logic gate 340. The “CBT_CS_P” pulses can further cause and/or allow the logic gate 344 to generate and send one or more signals (“LFSR_P” shown in FIG. 3A and in forms of pulses) to a pseudo random combine pointer 326 (analogous to the pseudo random combine pointer 226-1 and/or 226-2 illustrated in FIG. 2) as well as to a delay component 353.

As shown in FIG. 3A-3B, the pseudo random combine pointer 326 includes a shifter register, such as a linear-feedback shifter register (LFSR) 348. The LFSR 348 can generate a number of random bits (“PR_CA<6:0>” shown in FIG. 3B) with a quantity of bits equal to a quantity of “test data” received from the controller 104 shown in FIG. 1. For example, if “test data” received respectively at each memory die of interconnected memory dice (e.g., memory dice 220-1 and 220-2) has 7 bits, random bits generated at the LFSR 348 can further be of 7 bits. Although random bits generated at the LFSR 348 are illustrated as being 7 bits, embodiments are not limited to a particular quantity of random bits that can be generated at the LFSR 348.

A count component 350 can receive random bits from the LFSR 348 and count a quantity of “1”s within random bits. A quantity of “1”s determined as being within random bits can be indicated via a binary code. For example, as shown in FIG. 3B, random bits having no “1”s can be indicated via a binary code “000”; random bits having one “1” can be indicated via a binary code “001”; random bits having two “1”s can be indicated via a binary code “010”; random bits having three “1”s can be indicated via a binary code “011”; random bits having four “1”s can be indicated via a binary code “100”; random bits having five “1”s can be indicated via a binary code “101”; random bits having six “1”s can be indicated via a binary code “110”; and random bits having seven “1”s can be indicated via a binary code “111”. The binary code (e.g., one of those seven binary codes) can be provided to a selector 352, which can be a test mode register setting (shown as “TMRS” in FIG. 3B).

The selector 352 can output one or more signals (“DET34F” shown in FIG. 3B and in forms of pulses) upon the received binary code indicating that random bits have either three or four “1”s. Although FIG. 3A-3B illustrate a circuit/component designed to determine whether random bits of 7 bits have three or four “1”s, embodiments are not limited to a particular quantity of bits that random bits include or a particular quantity (e.g., three or four) of “1”s for which random bits are being examined. For example, the selector 352 can provide the signals upon the received binary code indicating that random bits have two, three, four, or five “1”s.

The delay component 353 can “mirror” input pulses (“LFSR_P” shown in FIG. 3A) received from the logic gate 344 to generate and send one or more pulses (“lat34” shown in FIG. 3B). The delay component 353 introduces a time delay between input pulses (“LFSR_P” shown in FIG. 3A) and output pulses (“lat34” shown in FIG. 3B) to synchronize a timing in which “DET34F” and “lat34” signals are received at a sequential logic circuit 354 (e.g., flip-flop). The sequential logic circuit 354 can generate and provide a signal (“HIT34F” shown in FIG. 3B) responsive to receiving both “DET34F” and “lat34” signals respectively from the selector 352 and delay component 353.

The bus training circuit 309 further includes a sequential logic circuit 357 (e.g., flip-flop) that can receive a signal indicative of a bus training initialization command (“CBT_INIT” shown in FIG. 3A) and a signal from the delay component 353 and that is analogous to “lat34” signal provided to the sequential logic circuit 354. The sequential logic circuit 357 can generate and send a signal (“initF” shown in FIG. 3B) to a logic gate 356 (e.g., XOR gate), which can further generate and send an output signal to the logic gate 358.

The delay component 355 can further mirror input signals received from the delay component 353 to generate and send one or more signals (e.g., in forms of pulses) to a logic gate 358 (e.g., AND gate). The delay component 353 introduces a time delay between input signals received from the delay component 353 and output signals of the delay component 355 to synchronize a timing in which signals from the logic gate 356 and the delay component 355 are received at the logic gate 358.

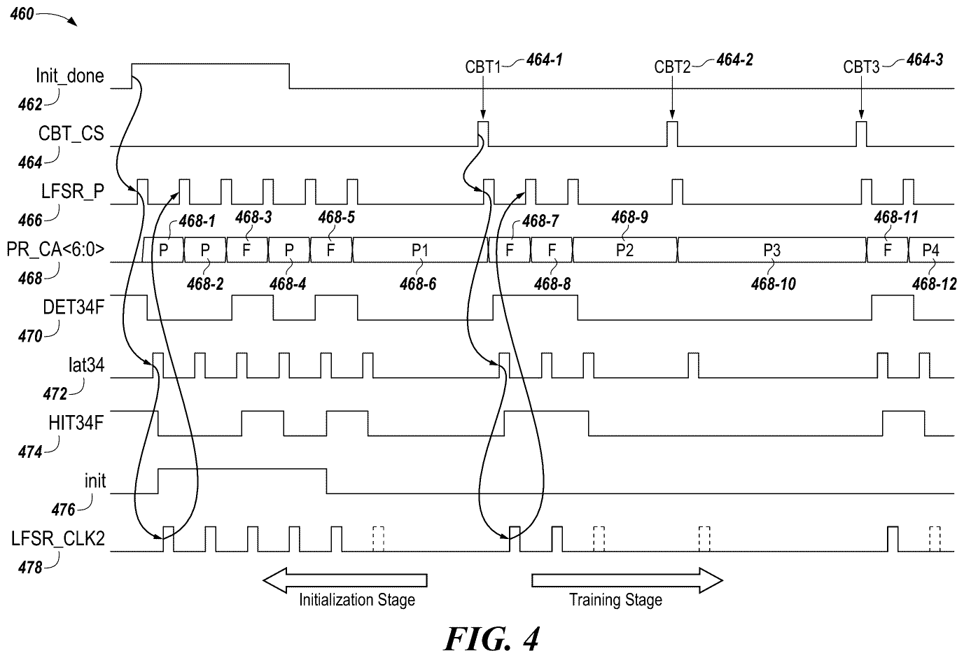

A signal can be delayed via delay components 353, 355, logic gate 358, and pulse re-adjustment component 343 in various forms (e.g., “LFSR_P”, “LFSR_CLK2”, etc.) as long as random bits generated at the LFSR 348 are indicated as not having three or four “1”s (e.g., as long as “HIT34F” is driven high as illustrated in FIG. 4). For example, a signal (“LFSR_CLK2” shown in FIG. 3A) outputted at the logic gate 358 can be input to the pulse re-adjustment component 343, which can be further input to (e.g., LFSR 348 of) the pseudo random combine pointer 326.

The pulse re-adjustment component 343 can readjust a pulse width of a “LFSR_CLK2” pulse, which may have experienced undesirable distortion due to PVT variation while circulating through the circuitry (e.g., delay components 353, 355, logic gate 358, and pulse re-adjustment component 343 illustrated in FIG. 3A). For example, a pulse width (of the “LFSR_CLK2” pulse) may have been increased while circulating through circuits (e.g., inverters) of the delay components 353, 355. The pulse re-adjustment component 343 can generate (e.g., create) a pulse (that is to be input to the logic gate 344) by generating two pulses with the same increased width: a first pulse starting with a rising edge and a second pulse starting with a falling edge. The time between the rising edge (of the first pulse) and falling edge (of the second pulse) can corresponds to the desired pulse width of the LFSR_P” pulse. The increase introduced by the pulse re-adjustment component 343 can correspond to the gate delay (e.g., of two inverters) in addition to the increased pulse width of the “LFSR_CLK2” pulse as received at the pulse re-adjustment component 343. A pulse width of the “LFSR_CLK2” pulse can be readjusted each time the pulse is received at the pulse re-adjustment component 343.

Once random bits are indicated as having three or four “1”s, a LFSR 348 can send (e.g., latch) the random bits (having three or four “1”s) to the sequential logic circuit 347. In response to receiving the random bits, a sequential logic circuit 347 (e.g., flip-flop) can generate and send “random pointer” bits to a selector 324 to cause and/or allow the selector 324 to select and combine input bits (e.g., “test data” received respectively from memory dice, such as memory dice 220-1 and 220-2) based on the “random pointer” bits. For example, if each input (“CBT data from LK DIE” and “CBT data from IF DIE”) has seven bits, the selector 324 can combine inputs from both memory dice to generate and output seven bits having three and four bits respectively from two memory dice. As illustrated herein, an output can be sent (e.g., transmitted) on a DQ bus (e.g., the DQ bus 228 illustrated in FIG. 2) as feedback data and a response to a CBT operation.

FIG. 4 illustrates a timing diagram 460 for performing a bus training operation (e.g., CBT operation) on interconnected memory dice (e.g., memory dice 220-1, 220-2 illustrated in FIG. 2) in accordance with a number of embodiments of the present disclosure. The timing diagram 460 illustrates signals “Init done” 462 (analogous to “CBT INIT” shown in FIG. 3A), “CBT_CS” 464 (analogous to “CBT start” shown in FIG. 3A), “LFSR_P” 466 (analogous to “LFSR_P” shown in FIG. 3A), “PR_CA<6:0>” 468 (analogous to “PR_CA<6:0>” shown in FIG. 3B), “DET34F” 470 (analogous to “DET34F” shown in FIG. 3B), “lat34” 472 (analogous to “lat34” shown in FIG. 3B), “HIT34F” 474 (analogous to “HIT34F” shown in FIG. 3B), “init” 476 (analogous to “initF” shown in FIG. 3B), and “LFSR_CLK2” 478 (analogous to “LFSR_CLK2” shown in FIG. 3A).

An initialization stage (analogous to a bus training initialization operation) can be initiated upon the signal 462 being driven high as illustrated in FIG. 4 (e.g., driven high in response to “CBT_INIT” signal being received at the logic gate 340 illustrated in FIG. 3A). In response to the bus training initialization command, the “init” signal 476 can be further driven high as illustrated in FIG. 4.

While the signal 462 is being driven high, a signal 464 can be periodically toggled to generate pulses on the “LFSR_P” signal 466. As used herein, the term “toggling” or the similar (e.g., toggled) refers to a change in the state of the signal, such as from low state (simply referred to as “low”) to high (simply referred to as “high”) or high to low. For example, each pulse on the “LFSR_P” signal 466 involves toggling the “LFSR_P” signal 466 twice to respectively create rising and falling edges of each pulse.

As illustrated in FIG. 4, each “LFSR_P” pulse can further cause generation of a respective “lat34” pulse on the “lat34” signal 472; each “lat34” pulse can further cause generation of a respective “LFSR_CLK2” pulse on the “LFSR_CLK2” signal 478; and each “LFSR_CLK2” pulse can again cause generation of a respective “LFSR_P” pulse on the “LFSR_P” signal 466. During the initialization stage, “LFSR_P”, “lat34” and “LFSR_CLK2” pulses can be continuously generated until both “init” signal 476 and “LFSR_CLK2” signal 478 are driven low.

Each “LFSR_P” pulse can cause LFSR 348 to further generate each number of random bits “PR_CA<6:0>”, such as 468-1, . . . , 468-12. “P” on the signal 468 indicates that a number of random bits (e.g., 7 bits) includes a desired number (e.g., three or four) of “1”s, while “F” on the signal 468 indicates the contrary (e.g., a number of random bits does not include a desired number of “1”s). For example, in the example illustrated in FIG. 4 and during the initialization stage, there illustrated four sets (e.g., numbers) of random bits 468-1, 468-2, 468-4, and 468-6 being marked as “P” (e.g., indicated as having a desired number of “1”s) and two sets 468-3 and 468-5 being marked as “F” (e.g., indicated as not having a desired number of “1”s).

A “DET34F” signal 470 is driven low in response to respective sets of random bits 468-1, 468-2, 468-4, and 468-6 being marked as “P” and is driven high in response to respective sets of random bits being marked as “F”. Similarly, “HIT34F” signal 474 is driven low in response to respective sets of random bits 468-3 and 468-5 being marked as “P” and is driven high in response to respective sets of random bits being marked as “F”.

A training stage (analogous to a bus training operation) can be initiated in response to each pulse on the “CBT_CS” signal 464 that can be generated in response to a respective bus training command. Each bus training command can toggle the “CBT_CS” signal 464 to generate a respective pulse (e.g., “CBT1, “CBT2”, and “CBT3” pulses 464-1, 464-2, and 464-3). Each CBT pulse on the signal 464 can cause generation of continuous and periodic pulses on the “LFSR_P” signal 466 as shown in FIG. 4. As further shown in FIG. 4, each pulse on the “LFSR_P” signal 466 can further cause generation of a respective pulse on the “lat34” signal 472, which can further cause generation of a respective pulse on the “LFSR_CLK2” signal 478. The pulse on the “LFSR_CLK2” signal 478 can again cause generation of a respective pulse on the “LFSR_P” signal 466.

Pulses on the signals 466, 472, and 478 can be continuously and periodically generated unless one set of random bits generated in response to each pulse on the “LFSR_P” signal 466 is indicated as having a desired (e.g., three or four) number of “1”s. Once “DET34F” and “HIT34” signals 470 and 474 are driven low due to one set of random bits (e.g., sets of random bits 468-9, 468-10, and 468-12) being determined to have a desired number of “1”s, a pulse is no longer generated on the “LFSR_CLK2” signal 478, which causes a corresponding set of random bits to latch to the sequential logic circuit 347 and further to the selector 324.

As shown in FIG. 4, for example, first two sets of random bits 468-7 and 468-8 generated in response to the “CBT1” pulse on the “CBT_CS” signal 464 are determined as not having a desired number of “1”s and can be respectively marked as “F”. Pulses that have been periodically generated on the “LFSR_CLK2” signal 478 are no longer generated once a third set of random bits 468-9 (marked as “P2”) is determined as having a desired number of “1”s. Further, a first set of random bits 468-10 (marked as “P3”) generated in response to the “CBT2” pulse on the “CBT_CS” signal 464 are determined as having a desired number of “1”s, which causes pulses on the “LFSR_CLK2” signal 478 to be no longer generated. Further, a first set of random bits 468-11 generated in response to the “CBT3” pulse on the “CBT_CS” signal 464 are determined as not having a desired number of “1”s and can be respectively marked as “F”. Pulses that have been periodically generated on the “LFSR_CLK2” signal 478 are no longer generated once a second set of random bits 468-12 (marked as “P4”) is determined as having a desired number of “1”s.

FIG. 5A-5C illustrate a sequence of example output bits generated from a pseudo random combine pointer (e.g., the pseudo random combine pointer 226 and/or 326 shown in FIGS. 2 and 3, respectively) in accordance with a number of embodiments of the present disclosure. More particular, the sequence of example output bits illustrated in FIG. 5A-5C can be generated as a result of testing of the pseudo random combine pointer 226 and/or 326.

Columns 580-1, . . . , 580-7 respectively illustrate bits on a DQ bus (e.g., the DQ bus 228 illustrated in FIG. 2). For example, a column 580-1 illustrates a bit value (alternatively referred to as a binary value) of a “DQ6” bit; a column 580-2 illustrates a bit value of a “DQ5” bit; a column 580-3 illustrates a bit value of a “DQ4” bit; a column 580-4 illustrates a bit value of a “DQ3” bit; a column 580-5 illustrates a bit value of a “DQ2” bit; a column 580-6 illustrates a bit value of a “DQ1” bit; and a column 580-7 illustrates a bit value of a “DQ0” bit.

Column 582 illustrates two hexadecimal (“HEX” shown in FIG. 5A-5C) values, with the left hexadecimal value representing a hexadecimal value of three digits of binary values 580-1, . . . , 580-3 and the right hexadecimal value representing a hexadecimal value of four digits of binary values 580-4, . . . , 580-7. Column 584 illustrates a number of “1”s in each row of 7 bits respectively corresponding to DQ0, . . . , DQ7. For example, an example row 585 is illustrated as having bits “0101011” that includes four “1”s with a hexadecimal value of “2” on left three digits of the bits “010” and a hexadecimal value of “B” on right four digits of the bits “1011”.

A sequence of sets of 7 bits illustrated in FIG. 5A-5C can be example output bits that can be outputted from (e.g., the selector 224-1 of) the memory die 220-1 as a result of the testing of the pseudo random combine pointer 226 as described in connection with FIG. 2. For example, a sequence of sets (respectively corresponding to rows) of output bits can be outputted from the memory die 220-1 independently of (e.g., without) input test data that would have been sent to the memory dice 220 as part of the CBT operation. Accordingly, a sequence of sets of output bits can be continuously provided from the memory die 220-1 independently of (e.g., regardless of) whether a number of “1”s in each set of output bits has three or four “1”s.

The sets of output bits outputted as a result of the testing of the pseudo random combine pointer 226 can be utilized for various configurations associated with a bus training operation (e.g., CBT operation). For example, the sets of output bits indicated by 586 in FIG. 5A indicate that it takes six clock cycles at the most to reach at another set of output bits having three or four “1”s. More particularly, as indicated by 586 in FIG. 5A, once it hits three “1”s at a set of output bits of “111000” having hexadecimal values “7” and “0”, it takes six cycles to reach at “000111” having three “1”s and hexadecimal values “0” and “E”. Therefore, this “six” clock cycles can be used as the worst case scenario for the circuit design (of the bus training circuit 109) and/or in configuring a tCACD, which refers to a time that can be taken between two CBT operations. In some embodiments, tCACD can be configured as 20 nanoseconds (ns).

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
responsive to receiving a bus training command and test data associated with the bus training command and having a first quantity of bits, generating a first number of random pointer bits having the first quantity of bits;
responsive to determining that the first number of random pointer bits has a second quantity of bits having a first binary value, generating combined feedback data based on the first number of random pointer bits by randomly combining first feedback data corresponding to the first test data received at a first memory die and second feedback data corresponding to the first test data received at the second memory die to generate combined feedback data, the combined feedback data comprising:
a portion of the first feedback data having the second quantity of bits; and
a portion of the second feedback data having a third quantity of bits; and
sending the feedback data on an external data bus coupled to the first memory die or the second memory die as a response to the bus training command.

2. The method of claim 1, further comprising responsive to determining that the first number of random pointer bits has the third quantity of bits having the first binary value, generating the combined feedback data based on the first number of random pointer bits by randomly combining the first feedback data and the second feedback data to generate the combined feedback data, the combined feedback data comprising:
a portion of the first feedback data having the third quantity of bits; and
a portion of the second feedback data having the second quantity of bits.

3. The method of claim 1, wherein:
the first memory die corresponds to a primary memory die coupled to the external data bus;
the second memory die corresponds to a secondary memory die internally coupled to the primary memory die; and
the method further comprises:
receiving the first test data at the second memory die; and
responsive to receiving the first test data, sending the second feedback data to the first memory die to allow the second feedback data to be randomly combined with the first feedback data.

4. The method of claim 1, further comprising:
responsive to determining that the first number of random pointer bits has a fourth quantity of bits having the first binary value, generating a second number of random pointer bits; and
responsive to determining that the second number of random pointer bits has the first or second quantity of bits having the first binary value, generating the combined feedback data based on the second number of random pointer bits by randomly combining the first feedback data and the second feedback data to generate the combined feedback data, the combined feedback data comprising:
a portion of the first feedback data having the third quantity of bits; and
a portion of the second feedback data having the second quantity of bits.

5. The method of claim 1, further comprising generating a sequence of numbers of random pointer bits responsive to receiving a bus training initialization command and regardless of whether each number of random pointer bits of the sequence has the second quantity of bits having the first binary value or not.

6. An apparatus, comprising:
a first memory die coupled to a substrate via an external data bus and a command/address (CA) bus; and
a second memory die coupled to the CA bus and internally to the first memory die;
the first memory die configured to:
in response to receipt of a first bus training command including first test data having a first quantity of bits, generate a first number of random pointer bits having the first quantity of bits;
in response to the first number of random pointer bits being determined as having a second quantity of bits having a first binary value, generate first combined feedback data based on the first number of random pointer bits, the first combined feedback data including a portion of first feedback data having the second quantity of bits and a portion of second feedback data having a third quantity of bits, wherein:
the first feedback data corresponds to the first test data received at the first memory die; and
the second feedback data corresponds to the first test data received at the first memory die; and
send the first combined feedback data on the external data bus.

7. The apparatus of claim 6, wherein the first memory die is configured to:
in response to the first number of random pointer bits being determined as having a fourth quantity of bits having the first binary value, generate a second number of random pointer bits having the first quantity of bits;
in response to the second number of random pointer bits being determined as having the second quantity of bits having the first binary value, generate second combined feedback data based on the second number of random pointer bits, the second combined feedback data including a portion of the first feedback data having the second quantity of bits and a portion of the second feedback data having the third quantity of bits; and
send the second combined feedback data on the external data bus.

8. The apparatus of claim 6, wherein the first combined feedback data includes:
the portion of the first feedback data on bit positions of the first combined feedback data that respectively correspond to bit positions of the first number of random pointer bits having the first binary value; and
the portion of the second feedback data on respective bit positions of the first combined feedback data that respectively correspond to bit positions of the first number of random pointer bits having a second binary value.

9. The apparatus of claim 6, wherein each bit position of the first combined feedback data further corresponds to a respective pin of the external data bus.

10. The apparatus of claim 6, wherein a sum of the second quantity and the third quantity equals to the first quantity.

11. The apparatus of claim 6, wherein:
the second memory die is internally coupled to the first memory die via a wire link; and
the second memory die is configured to send the second feedback data to the first memory die via the wire link to allow the first memory die to combine the first and second feedback data.

12. The apparatus of claim 6, wherein the second memory die is not coupled to the substrate.

13. The apparatus of claim 6, wherein the first memory die is configured to generate, in response to a bus training initialization command received prior to the bus training command, a sequence of numbers of random pointer bits regardless of whether a respective one of the number of random pointer bits is determined to have the second quantity of bits having the first binary value.

14. An apparatus, comprising:
a first memory die coupled to a substrate via a first external data bus and a command/address (CA) bus; the first memory die configured to send first feedback data in response to receipt of test data having a first quantity of bits via the CA bus; and
a second memory die coupled to the CA bus and internally to the first memory die, the second memory die configured to send second feedback data in response to receipt of the test data via the CA bus;
the first memory die comprising a bus training logic, the bus training logic configured to:
in response to receipt of a bus training command including the test data via the CA bus, continuously generate a sequence of numbers of random pointer bits until one number of random pointer bits of the sequence is determined to have a second or third quantity of bits having a first binary value;
generate combined feedback data comprising:
a portion of the first feedback data on bit positions of the combined feedback data that respectively correspond to bit positions of the one number of random pointer bits having the first binary value; and
a portion of the second feedback data on respective bit positions of the combined feedback data that respectively correspond to bit positions of the one number of random pointer bits having a second binary value; and
send the combined feedback data on the external data bus.

15. The apparatus of claim 14, wherein:
the second memory die is internally coupled to the first memory die via a wire link; and
the second memory die is configured to send the second feedback data to the first memory die via the wire link to allow the first memory die to combine the first and second feedback data.

16. The apparatus of claim 14, wherein a sum of the second quantity and the third quantity equals to the first quantity.

17. The apparatus of claim 14, wherein the first memory die further comprises a shifter register configured to generate the sequence of the number of random pointer bits.

18. The apparatus of claim 17, wherein the shifter register is further configured to continuously generate a sequence of numbers of random bits each having the first quantity in response to a bus training initialization command received prior to the bus training command and regardless of whether a respective number of random bits of the sequence is determined to have the second or third quantity of bits having the first binary value.

19. The apparatus of claim 18, wherein:
the shifter register is configured to generate each number of random bits of the sequence in response to a respective one of a number of input pulses received at the shifter register, wherein each input pulse of the number of input pulses has a first pulse width; and
wherein the apparatus further comprises a pulse width readjuster coupled to the shifter register, the pulse width readjuster configured to readjust an increased second pulse width of a respective input pulse of the number of input pulses to the first pulse width.

20. The apparatus of claim 14, further comprising a controller coupled to the first and second memory dice, wherein the controller is configured to:
cause the second memory die to output a first number of bits having the first binary value and send the first number of bits to the first memory die; and
cause the first memory die to output a second number of bits having the second binary value and randomly combine the first number of bits and the second number of bits to generate a third number of bits, the third number of bits comprising:
a portion of the first number of bits having the second quantity and having the first binary value; and
a portion of the second number of bits having the third quantity and having the second binary value.
